(19) United States
(12) Patent Application Publication
(10) Pub. No.: US 2009/0008652 A1
(43) Pub. Date: Jan. 8, 2009

(54) Free-Standing Substrate, Method for Producing the Same and Semiconductor Light-Emitting Device

(75) Inventors: Kazumasa Ueda, Ibaraki (JP); Naohiro Nishikawa, Ibaraki (JP); Yoshihiko Tsuchida, Ibaraki (JP)

Correspondence Address: FITCH, EVEN, TABIN & FLANNERY, P. O. BOX 18415, WASHINGTON, DC, 20036, US

(73) Assignee: Sumitomo Chemical Company, Ltd., Tokyo (JP)

(21) Appl. No.: 11/908,539

(22) PCT Filed: Mar. 20, 2006
(86) PCT No.: PCT/JP2006/306068

§ 371 Date: Sep. 13, 2007

(30) Foreign Application Priority Data
Mar. 22, 2005 (JP) 2005-081358
May 18, 2005 (JP) 2005-145465
May 27, 2005 (JP) 2005-156172

(51) Int. Cl. H01L 21/28; H01L 29/12

(52) U.S. Cl. 257/79; 257/618; 438/483; 257/E29.068; 257/E21.158

(57) ABSTRACT

The present invention provides a free-standing substrate, a method for producing the same and a semiconductor light-emitting device. The free-standing substrate comprises a semiconductor layer and inorganic particles, wherein the inorganic particles are included in the semiconductor layer. The method for producing a free-standing substrate comprises the steps of: (a) placing inorganic particles on a substrate, (b) growing a semiconductor layer thereon, and (c) separating the semiconductor layer from the substrate, in that order. The semiconductor light-emitting device comprises the free-standing substrate, a conductive layer, a light-emitting device, and electrodes.

### TECHNICAL FIELD

The present invention relates to a free-standing substrate, a method for producing the substrate, and a semiconductor light-emitting device. More particularly, the invention relates to a group III-V nitride semiconductor free-standing substrate, a method for producing the substrate, and a semiconductor light-emitting device.

### BACKGROUND ART

Group III-V nitride semiconductors are used to produce semiconductor light-emitting devices for display units. For example, a group III-V nitride semiconductor represented by the formula InₓGa_{y}Al_{z}N (0≦x≦1, 0≦y≦1, 0≦z≦1, and x+y+z=1) is used to produce semiconductor light-emitting devices such as ultraviolet, blue, or green light-emitting diodes or ultraviolet, blue, or green laser diodes.

Since it is difficult to produce group III-V nitride semiconductors by means of bulk crystal growth, these semiconductors are usually produced by epitaxially growing a group III-V nitride semiconductor layer on a substrate made of a substance other than a group III-V nitride semiconductor (such as sapphire) by means of metal organic vapor phase epitaxy or the like. However, since sapphire substrates differ from group III-V nitride semiconductors in lattice constant and thermal expansion coefficient, the group III-V nitride semiconductor layers have high-density dislocations. And further, when a layered substrate are produced by growing plural group III-V nitride semiconductor layers, warpage occurred in the layered substrate or the layered substrate is broken.

In order to solve these problems, a semiconductor light-emitting device in which a nitride semiconductor layer is formed on a GaN substrate is proposed (JP-A-2000-223743).

However, such a semiconductor light-emitting device does not have sufficient brightness. In viewpoint of improving the performance of display units, a higher brightness semiconductor light-emitting device and a free-standing substrate to produce the light-emitting device are required.

### DISCLOSURE OF THE INVENTION

In order to solve the above problems, the present inventors conducted extensive studies on a high brightness semiconductor light-emitting device and a free-standing substrate in order to produce the light-emitting device and then have accomplished the invention.

That is, the invention provides a free-standing substrate comprising a semiconductor layer and inorganic particles, wherein the inorganic particles are included in the semiconductor layer.

The invention provides a method for producing a free-standing substrate comprising the steps of:

(a) placing inorganic particles on a substrate,
(b) growing a semiconductor layer thereon, and
(c) separating the semiconductor layer from the substrate, in that order.

The invention provides a method for producing a free-standing substrate comprising the steps of:

(s1) growing a buffer layer on a substrate,
(a) placing inorganic particles on the buffer layer,
(b) growing a semiconductor layer thereon; and
(c) separating the semiconductor layer from the substrate, in that order.

Moreover, the invention provides a semiconductor light-emitting device comprising the free-standing substrate, a conductive layer, a light-emitting layer, and electrodes.

### BRIEF DESCRIPTION OF THE DRAWINGS

FIG. 1 shows a structure of semiconductor light-emitting device.

FIG. 2 shows an embodiment a free-standing substrate to which a support member is attached.

FIG. 3 shows another embodiment of a free-standing substrate to which a support member is attached.

FIG. 4 shows a method for producing a free-standing substrate.

FIG. 5 shows another method for producing a free-standing substrate.

FIG. 6 shows a method for producing a free-standing substrate including a step of growing a buffer layer.

FIG. 7 shows another method for producing a free-standing substrate including a step of growing a buffer layer.

FIG. 8 shows a substrate before separating a semiconductor layer from the substrate described in Example 1.

FIG. 9 shows a free-standing substrate and a substrate after separating the semiconductor layer from the substrate described in Example 1.

FIG. 10 is a photograph of the surface of a substrate in which silica particles are placed obtained by the method for producing a free-standing substrate described in Example 2.

FIG. 11 shows a structure of a semiconductor light-emitting device.

### DESCRIPTION OF REFERENCE NUMERALS

1 semiconductor light-emitting device
3 n-type contact layer
4 light-emitting layer
5 p-type contact layer
6, 7 electrode
21, 31 substrate
21A, 22A surface
21B growth region
22 free-standing substrate
23, 24, 32 inorganic particles
22B, 25 group III-V nitride semiconductor layer
26 buffer layer
26B void
33 GaN buffer layer
34 undoped GaN layer
35 Si-doped GaN layer
36 GaN layer
37 light-emitting layer
37A InGaN layer
37B GaN layer
37C GaN layer
38 Mg-doped AlGaN layer
39 Mg-doped GaN layer
40 substrate of group III-V nitride semiconductor light-emitting device
101 metal plate
102 semiconductor light-emitting device package

### MODE FOR CARRYING OUT THE INVENTION

### Free-Standing Substrate

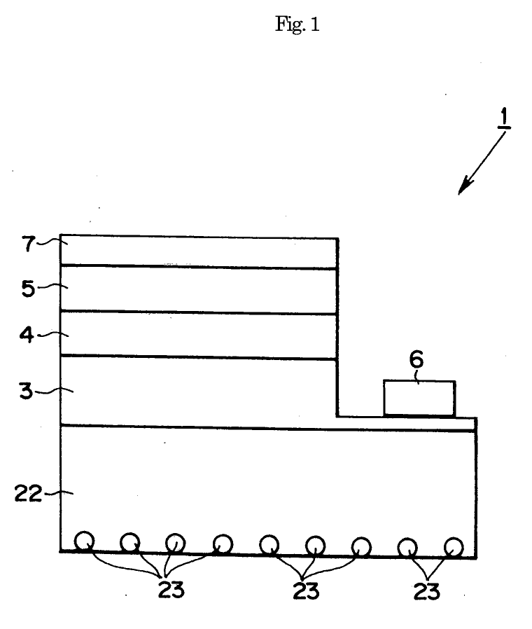

A free-standing substrate according to the present invention includes a semiconductor layer and inorganic particles. As shown in FIG. 1, the free-standing substrate including the semiconductor layer 22 and the inorganic particles 23 is used to produce a compound semiconductor device, such as a nitride semiconductor light-emitting device 1 including n-type contact layer 3, light-emitting layer 4, p-type contact layer 5, and electrodes 6 and 7, and no substrate made of sapphire.

### [Semiconductor Layer]

The semiconductor layer is usually made of a group III-V nitride and preferably made of a metallic nitride represented by the formula InₓGa_{y}Al_{z}N (0≦x≦1, 0≦y≦1, 0≦z≦1, and x+y+z=1). The composition of the semiconductor layer may be determined by using an X-ray diffraction or analyzing a cut surface of the free-standing substrate by means of SEM-EDX, for example.

Furthermore, the semiconductor layer may include, for example, a single layer, a multilayer (such as a thick-film layer and a superlattice thin-film layer), or a buffer layer to impart a high crystallinity to the layer required for the operation of the nitride semiconductor light-emitting device.

### [Inorganic Particles]

The inorganic particles are included in the semiconductor layer and contain an inorganic substance such as oxide, nitride, carbide, boride, sulfide, selenide, or metal. The inorganic substance content of the inorganic particles is usually not less than 50 wt %, preferably not less than 90 wt %, more preferably not less than 95 wt %. The composition of the inorganic particles included in the semiconductor layer may be determined by cutting the free-standing substrate and then analyzing the cut surface of the semiconductor layer by means of SEM-EDX.

Examples of the oxide include silica, alumina, zirconia, titania, ceria, zinc oxide, tin oxide, and yttrium aluminum garnet (YAG).

Examples of the nitride include silicon nitride and boron nitride.

Examples of the carbide include silicon carbide (SiC), boron carbide, diamond, graphite, and fullerene.

Examples of the boride include zirconium boride (ZrB₂) and chromium boride (CrB₂).

Examples of the sulfide include zinc sulfide, cadmium sulfide, calcium sulfide, and strontium sulfide.

Examples of the selenide include zinc selenide and cadmium selenide.

In the oxide, the nitride, the carbide, the boride, the sulfide, and the selenide, the element(s) other than oxygen, nitrogen, carbon, boron, sulfur, or selenium may be partially substituted with another element. Examples of the oxide in which the element other than oxygen is partially substituted with another element include a phosphor of silicate or aluminate including cerium or europium as an activator.

Examples of the metal include silicon (Si), nickel (Ni), tungsten (W), tantalum (Ta), chromium (Cr), titanium (Ti), magnesium (Mg), calcium (Ca), aluminum (Al), gold (Au), silver (Ag), and zinc (Zn).

As the inorganic particles, particles made of one of the above inorganic substances, particles made of a mixture of selected ones of these substances, or particles made of a composite comprised of selected ones of these substances may be used.

When the inorganic particles are made of an inorganic substance, the inorganic particles are made of preferably oxide, more preferably silica. As the mixture, a combination of silica particles and particles of the oxide other than silica is preferably used and a combination of silica particles and titania particles is more preferably used. Examples of the composite include a composite which contains nitride particles and oxide, the oxide is present on the nitride particles.

The inorganic particles preferably include a mask material for use in the growth of the semiconductor layer; more preferably, the mask material is present on their surfaces.

When the surfaces of the inorganic particles are covered with the mask material, it is preferable to cover not less than 30% of each surface therewith and it is more preferable to cover not less than 50% of each surface. Examples of themaskmaterial include silica, zirconia, titania, silicon nitride, boron nitride, tungsten (W), molybdenum (Mo), chromium (Cr), cobalt (Co), silicon (Si), gold (Au), zirconium (Zr), tantalum (Ta), titanium (Ti), niobium (Nb), nickel (Ni), platinum (Pt), vanadium (V), hafnium (Hf), and palladium (Pd), preferably silica. These materials may be used alone or in combination. The composition of the mask material for the inorganic particles may be determined by cutting the semiconductor layered device and then analyzing the cross sections of the inorganic particles by means of SEM-EDX.

The inorganic particles may have the shape of sphere (for example, circular or elliptic cross section), plate (for example, an aspect (L/T) ratio of 1.5 to 100 where L is their length and T is their thickness), needle (for example, a L/W ratio of 1.5 to 100 where L is their length and W is their width), or no definite shape (they may have various shapes and be therefore uneven in shape as a whole), preferably sphere. And further, The inorganic particles may have an average particle diameter of usually not less than 5 nm, preferably not less than 10 nm, more preferably not less than 20 nm, usually not more than 50 μm, preferably not more than 10 μm, more preferably not more than 1 μm. The inclusion of the inorganic particles having an average particle diameter of the above range makes it possible to obtain a free-standing substrate acting as part of a high-brightness semiconductor light-emitting device. The shape and the average particle diameter of the inorganic particles may be determined from, for example, a photograph of the cross section of the semiconductor layer obtained by cutting the free-standing substrate and then photographing the cross section with an electron microscope.

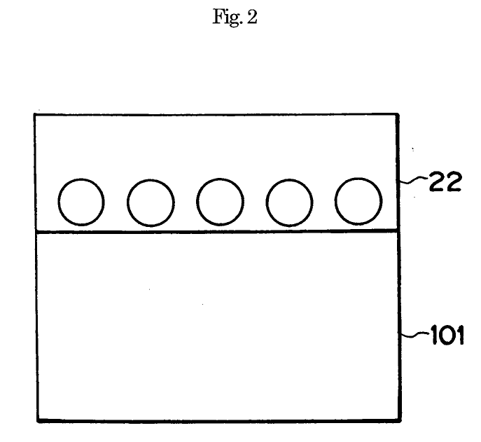

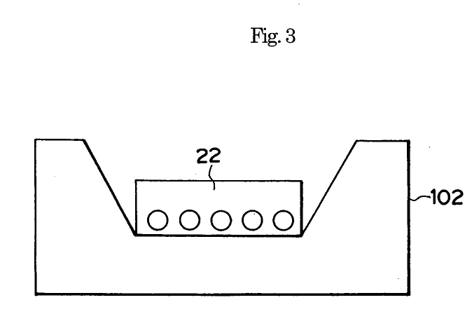

In viewpoint of improving heat release property or rigidity of the free-standing substrate, a support member may be attached thereto. The support member may be made of material having good heat release property or high rigidity. Examples of the material include metal and polymer resin. And further, as such metallic material, alloy such as low melting point alloy may be used; as such polymer resin, thermosetting resin or photosetting resin may be used. FIG. 2 shows an embodiment of the free-standing substrate 22 to which a metal plate 101 is attached as the support member. FIG. 3 shows an embodiment of the free-standing substrate 22 to which a package 102 for the semiconductor light-emitting device is attached as the support member. The free-standing substrate has a thickness of usually not less than 3 μm, preferably not less than 10 μm, usually not more than 500 μm, preferably not more than 100 μm, more preferably not more than 65 μm, further preferably not more than 45 μm. In the free-standing substrate to which the support member is attached, the thickness of the free-standing substrate does not include the thickness of the support member.

### Method for Producing Free-Standing Substrate

A method for producing a free-standing substrate according to the present invention includes a step (a) of placing the inorganic particles on a substrate or an optional buffer layer.

The substrate is made of, for example, sapphire, SiC, Si, MgAl₂O₄, LiTaO₃, ZrB₂, or CrB₂ and preferably sapphire, SiC, or Si.

The method for producing the free-standing substrate, may include a step (s1) of growing the buffer layer on the substrate. The buffer layer is usually made of a group III-V nitride represented by the formula InₓGa_{y}Al_{z}N (0≦x≦1, 0≦y≦1, 0≦z≦1, and x+y+z=1). The buffer layer may be grown as a single layer or more than one layer. The buffer layer may be grown by means of metalorganic vapor phase epitaxy (MOVPE), molecular beam epitaxy (MBE), or hydride vapor phase epitaxy (HVPE), at a temperature of 400° C. to 700° C.

The method for producing the free-standing substrate, may include a step (s2) of growing an InₓGa_{y}Al_{z}N layer (0≦x≦1, 0≦y≦1, 0≦z≦1, and x+y+z=1) on the buffer layer.

The inorganic particles contain an inorganic substance such as oxide, nitride, carbide, boride, sulfide, selenide, or metal. The inorganic substance content of the inorganic particles is usually not less than 50 wt %, preferably not less than 90 wt %, more preferably not less than 95 wt %. The composition of the inorganic particles may be determined by means of chemical analysis, emission spectroscopy, or the like.

Examples of the oxide include silica, alumina, zirconia, titania, ceria, zinc oxide, tin oxide, and yttrium aluminum garnet (YAG).

Examples of the nitride include silicon nitride and boron nitride.

Examples of the carbide include silicon carbide (SiC), boron carbide, diamond, graphite, and fullerene.

Examples of the boride include zirconium boride (ZrB₂) and chromium boride (Cr B₂).

Examples of the sulfide include zinc sulfide, cadmium sulfide, calcium sulfide, and strontium sulfide.

Examples of the selenide include zinc selenide and cadmium selenide.

In the oxide, the nitride, the carbide, the boride, the sulfide, and the selenide, the element other than oxygen, nitrogen, carbon, boron, sulfur, or selenium may be partially substituted with another element. Examples of the oxide in which the element other than oxygen is partially substituted with another element include a phosphor of silicate or aluminate including cerium or europium as an activator.

Examples of the metal include silicon (Si), nickel (Ni), tungsten (W), tantalum (Ta), chromium (Cr), titanium (Ti), magnesium (Mg), calcium (Ca), aluminum (Al), gold (Au), silver (Ag), and zinc (Zn).

As the inorganic particles, a material may be used which is converted to the oxide, nitride, carbide, boride, sulfide, selenide, or the metal by heat treatment; for example, silicone may be used. The silicone is a polymer with a structure in which its backbone is an inorganic bond of Si—O—Si and organic substituents are present at the Si portions. When heated to about 500° C., silicone is converted to silica.

As the inorganic particles, particles of one of the above inorganic substances, particles of a mixture of selected ones of these substance, or particles of a composite comprised of selected ones of these substances may be used. When the inorganic particles are made of an inorganic substance, the inorganic particles are made of preferably oxide, more preferably silica. As the mixture, a combination of silica particles and particles of the oxide other than silica is preferably used and a combination of silica particles and titania particles is more preferably used. Examples of the composite include a composite which contains nitride particles and oxide, the oxide is present on the nitride particles.

The inorganic particles preferably include a mask material for use in the growth of the semiconductor layer; more preferably, the mask material is present on their surfaces. When the surfaces of the inorganic particles are covered with the mask material, it is preferable to cover not less than 30% of each surface therewith and it is more preferable to cover not less than 50% of each surface. Examples of the mask material include silica, zirconia, titania, silicon nitride, boron nitride, tungsten (W), molybdenum (Mo), chromium (Cr), cobalt (Co), silicon (Si), gold (Au), zirconium (Zr), tantalum (Ta), titanium (Ti), niobium (Nb), nickel (Ni), platinum (Pt), vanadium (V), hafnium (Hf), and palladium (Pd), preferably silica. These materials may be used alone or in combination. In order to cover the surfaces of the inorganic particles with the mask material, a method, such as covering the surfaces of the particles with the mask material by means of vapor deposition or sputtering or hydrolyzing the compound on the surfaces of the particles, may be used.

The inorganic particles may have the shape of sphere (for example, circular or elliptic cross section), plate (for example, an aspect (L/T) ratio of 1.5 to 100 where L is their length and T is their thickness), needle (for example, a L/W ratio of 1.5 to 100 where L is their length and W is their width), or no definite shape (they may have various shapes and be therefore uneven in shape as a whole), preferably sphere. Therefore it is preferable that spherical silica may used as the inorganic particles. As spherical silica, colloidal silica is recommended in viewpoint of availability of silica particles which are mono-dispersed and has almost same diameter. Colloidal silica is a suspension in which silica particles are dispersed into a solvent (such as water) in colloidal form and such a suspension may be prepared through the ion exchange of sodium silicate or the hydrolysis of an organosilicon compound such as tetraethyl orthosilicate (TEOS). And further, the inorganic particles have an average particle diameter of usually not less than 5 nm, preferably not less than 10 nm, more preferably not less than 0.1 μm, usually not more than 50 μm, preferably not more than 10 μm, more preferably not more than 1 μm. The inclusion of the inorganic particles with an average particle diameter in one of the above ranges makes it possible to obtain a free-standing substrate which is used as semiconductor light-emitting device showing a high brightness.

Moreover, when a semiconductor light-emitting device is produced using the free-standing substrate including the inorganic particles, the ratio of d/λ (where d is the average particle diameter (nm) of the inorganic particles and λ is the wavelength (nm) of light from the semiconductor light-emitting device) is usually not less than 0.01, preferably not less than 0.02, more preferably not less than 0.2, usually not more than 100, preferably not more than 30, more preferably not more than 3.0.

The average particle diameter refers to a volumetric average particle diameter measured by means of centrifugal sedimentation. The average particle diameter may be measured by a method other than centrifugal sedimentation, such as a dynamic light-scattering, a Coulter counter, laser diffractometry, or electron microscopy; in that case, it is required only to calibrate the average particle diameter and then convert the diameter into the volumetric average particle diameter measured by means of centrifugal sedimentation. For example, the average particle diameter of standard ones of the particles is determined by means of centrifugal sedimentation and another method of measuring an average particle diameter, and then the correlation coefficient of their average particle diameters measured using these measurement method is calculated. It is preferable that the correlation coefficient is determined by calculating the correlation coefficient of various diameters of the plural standard particles to their volumetric average particle diameter measured by means of centrifugal sedimentation and then drawing a calibration curve. The use of the calibration curve makes it possible to determine the volumetric average particle diameter from the average particle diameter determined by a method other than centrifugal sedimentation.

The placement of the inorganic particles may be carried out by, for example, a method of dipping the substrate in a slurry comprised of the inorganic substance and a medium or a method of applying or spraying the slurry onto the substrate, and then drying the slurry. Examples of the medium include water, methanol, ethanol, isopropanol, n-butanol, ethylene glycol, dimethylacetamide, methyl ethyl ketone, and methyl isobutyl ketone, preferably water. The application is preferably carried out by spin coating, which makes it possible to uniform the placement density of the inorganic particles. The drying may be carried out using a spinner.

The coverage of the inorganic particles to the substrate may be determined from the following expression:

the coverage (%)=((d/2)²×π·P·100)/S

where d represents the average particle diameter of the inorganic particles and P represents the number of the particles in a visual field (an area S) measured when the surface of the substrate, in which the inorganic particles are placed, is observed from above using a scanning electron microscope (SEM).

When the inorganic particles are comprised of one inorganic substance, the coverage of the inorganic particles to the substrate is usually not less than 1%, more preferably not less than 30%, more preferably not less than 50%, usually not more than 95%, preferably not more than 90%, more preferably not more than 80%.

In viewpoint of epitaxially growing a semiconductor layer which is flattened, the inorganic particles are usually placed on the substrate as a single layer, and therefore, for example, not less than 90% of the inorganic particles are placed thereon as a single layer. However, the particles may be placed thereon as more than one layer provided that the semiconductor layer is epitaxially grown and flattened; therefore one type of the inorganic particles may be placed thereon as at least two layers or at least two kinds of the inorganic particles may be respectively placed thereon as a single layer. When at least two kinds of the inorganic particles, like titania particles and silica particles, are placed thereon, the coverage of the first placed inorganic particles (the titania particles, for example) to the substrate is usually not less than 1%, preferably not less than 30%, usually not more than 95%, preferably not more than 90%, more preferably not more than 80%. The coverage of the inorganic particles placed for the second and subsequent times (the silica particles, for example) to the substrate is usually not less than 1%, preferably not less than 30%, more preferably not less than 50%, usually not more than 95%, preferably not more than 90%, more preferably not more than 80%.

The method according to the invention further includes a step (b) of growing a semiconductor layer on the layer grown at the step (a).

The semiconductor layer is made of, for example, a group III-V nitride represented by the formula InₓGa_{y}Al_{z}N (0≦x≦1, 0≦y≦1, 0≦z≦1, and x+y+z=1). The semiconductor layer may grown as a single layer or more than one layer.

Furthermore, the semiconductor layer may be either a semiconductor layer at which a facet structure is formed or one at which a facet structure is not formed; when the coverage of the inorganic particles thereto is high, preference is given to the semiconductor layer at which the facet layer is formed. The semiconductor layer at which the facet structure is formed is easy to flatten.

In cases where the semiconductor layer is grown while forming the facet structure, the preferred composition of the group III-V nitride semiconductor layer depends on the diameter and the placement status of the inorganic particles; when the coverage of the inorganic particles thereto is high, it is preferable that its Al content is high. However, in a case where an embedded layer is a GaN layer or an AlGaN layer with an Al content which is lower than the Al content of in the facet structure, when the Al content of the group III-V nitride semiconductor layer is too high, lattice mismatching between the embedded layer and the facet structure becomes large, which may cause cracks and dislocations in the substrate.

The Al content in the facet structure can be regulated based on the diameter and the placement status of the inorganic particles to form a crystal which is not cracked and is excellent in crystallinity. For example, when the coverage of the inorganic particles thereto is above 50%, it is preferable to grow the semiconductor layer with the facet structure represented by the formula Al_{d}Ga_{1-d}N [0≦d≦1] and it is preferable to grow the semiconductor layer with the facet structure represented by the formula Al_{d}Ga_{1-d}N [0.01≦d≦0.5] (the mole fraction of Al/N is in the range of 1.0% to 50%).

A growth temperature of facet structure is usually not less than 700° C., preferably not less than 750° C., usually not more than 1000° C., more preferably not more than 950° C. In case the buffer layer is grown on the substrate, the growth temperature for the semiconductor layer with the facet structure is preferably between a growth temperature for the buffer layer and a growth temperature for the embedded layer. The facet layer may be grown as a single layer or more than one layer.

The growth of the semiconductor layer with the facet structure may be carried out by means of epitaxial growth such as metalorganic vapor phase epitaxy (MOVPE), molecular beam epitaxy (MBE), or hydride vapor phase epitaxy (HVPE).

When the group III-V nitride semiconductor layer is grown by means of MOVPE, the growth may be carried out by a method in which a group III material and a group V material are introduced into a reactor using a carrier gas.

Examples of the group III material include:

trialkyl gallium represented by the formula R₁R₂R₃Ga [where R₁, R₂, and R₃ are lower alkyl groups] such as trimethyl gallium [TMG, (CH₃)₃Ga] and triethyl gallium [TEG, (C₂H₅)₃Ga];
trialkyl aluminum represented by the formula R₁R₂R₃Al [where R₁, R₂, and R₃ are lower alkyl groups] such as trimethyl aluminum [TMA, (CH₃)₃Al], triethyl aluminum [TEA, (C₂H₅)₃Al], and triisobutyl aluminum [(i-C₄H₉)₃Al];
trimethylamineallan [(CH₃)₃N:AlH₃];
trialkyl indium represented by the formula R₁R₂R₃In [where R₁, R₂, and R₃ are lower alkyl groups] such as trimethyl indium [TMI, (CH₃)₃In] and triethyl indium [(C₂H₅)₃In];
compounds given by substituting one or two alkyl groups of trialkyl indium with one or two halogen atoms such as diethyl indium chloride [(C₂H₅)₂InCl]; and
indium halide represented by the formula InX [where X is a halogen atom] such as indium chloride [InCl].
These materials may be used alone or in combination.

Among the group III materials, TMG is preferable as a gallium source, TMA is preferable as an aluminum source, and TMI is preferable as an indium source.

Examples of the group V material include ammonia, hydrazine, methylhydrazine, 1,1-dimethylhydrazine, 1,2-dimethylhydrazine, t-butylamine, and ethylenediamine. These materials may be used alone or in combination. Among the group V materials, ammonia and hydrazine are preferred; ammonia is much preferred.

Examples of an element used as a n-type dopant include Si and Ge. Examples of a material used as the n-type dopant include silane, disilane, germane, and tetramethyl germanium.

Examples of an element used as a p-type dopant include Mg, Zn, Cd, Ca, and Be; preference is given to Mg and Ca.

Examples of a Mg material used as the p-type dopant include bis(cyclopentadienyl) magnesium [(C₅H₅)₂Mg], bis(methylcyclopentadienyl)magnesium [(C₅H₄CH₃)₂Mg], and bis(ethylcyclopentadienyl)magnesium [(C₅H₄C₂H₅)₂Mg]. Examples of a Ca material used as the p-type dopant include: bis(cyclopentadienyl)calcium [(C₅H₅)₂Ca] and its derivatives such as bis(methylcyclopentadienyl)calcium [(C₅H₄CH₃)₂Ca], bis(ethylcyclopentadienyl)calcium [(C₅H₄C₂H₅)₂Ca], and bis(perfluorocyclopentadienyl)calcium [(C₅F₅)₂Ca]; di-(1-naphthalenyl)calcium and its derivatives; and calcium acetylide and its derivatives such as bis(4,4-difluoro-3-butene-1-inyl)calcium and bis(phenylethynyl)calcium. These materials may be used alone or in combination.

Examples of an atmospheric gas and the carrier gas for the materials used at growth include nitrogen, hydrogen, argon, and helium, preferably hydrogen and helium. These gases may be used alone or in combination.

The reactor has usually a susceptor and a line through which the materials are introduced from a storage container to the reactor. The susceptor is an apparatus for heating the substrate and is placed in the reactor; and besides the susceptor is usually rotated with power to grow the semiconductor layer uniformly. The susceptor has a heating unit such as an infrared lamp inside. Through the provision of the heating unit, the materials introduced through the line to the reactor are pyrolyzed on the substrate to grow a semiconductor layer on the substrate. Of the materials introduced to the reactor, unreacted material is usually exhausted from the reactor to the outside through an exhaust line and then sent to a waste gas treatment unit.

When the group III-V nitride semiconductor layer is grown by HVPE, the growth may be carried out by a method in which a group III material and a group V material are introduced into the reactor using a carrier gas.

Examples of the group III material include a gallium chloride gas formed by reacting gallium and a hydrogen chloride gas at elevated temperature and an indium chloride gas formed by reacting indium and a hydrogen chloride gas at elevated temperature.

Examples of the group V material include ammonia.

Examples of the carrier gas include nitrogen, hydrogen, argon, and helium; preference is given to hydrogen and helium. These gases may be used alone or in combination.

Moreover, when the group III-V nitride semiconductor layer is grown by MBE, the growth may be carried out using a method in which a group III material and a group V material are introduced into the reactor using a carrier gas.

Examples of the group III material include metals such as gallium, aluminum, and indium.

Examples of the group V material include gases such as nitrogen and ammonia.

Examples of the carrier gas include nitrogen, hydrogen, argon, and helium; preference is given to hydrogen and helium. These gases may be used alone or in combination.

At step (b), the semiconductor layer usually starts to grow such that its growth region is grown at a place in which no inorganic particle is placed. Then the facet structure is formed.

Furthermore, the surface of the semiconductor layer may be flattened at step (b); for example, the flattening may be carried out by embedding the facet structure of the substrate formed by growing the semiconductor layer while forming the facet structure in the layer through the promotion of its lateral growth. Through such growth, dislocations having reached the facets are bent sideward and the inorganic particles are embedded in the semiconductor layer, which reduces crystal defects in the semiconductor layer.

Moreover, when the buffer layer is grown at step (s1), voids may be formed in the inorganic particle region and the substrate region of the buffer layer at step (b) due to the etching of the carrier gas (hydrogen) and the material (ammonia) on the buffer layer.

The semiconductor layer grown at step (b) has a thickness of usually not less than 3 μm, preferably not less than 10 μm, usually not more than 500 μm, preferably not more than 100 μm, more preferably not more than 65 μm, further preferably not more than 45 μm.

The method according to the invention further includes step (c) of removing the substrate.

The removal may be carried out by a method of removing the substrate from the semiconductor layered substrate formed at step (b) through the use of either a physical means such as internal stress or external stress or a chemical means such as etching.

The removal may be carried out by, for example, a method of cooling the semiconductor layer grown at step (b) in order to induce thermal stress (internal stress) through the difference in thermal expansion coefficient between the substrate and the semiconductor layer.

The removal may be carried out by means of polishing or laser lift-off. In this method, polishing or the like may be carried out after a rigid support substrate is attached to the semiconductor layer.

Furthermore, the removal may be carried out by a method of fixing one side of the substrate or the semiconductor layer and then applying an external force to the unfixed other side.

In the method according to the invention, steps of (a) and (b) may be repeatedly carried out. As step of (a), sub-step of (a1) of placing inorganic particles and sub-step of (a2) of placing another type of inorganic particles after sub-step of (a1) may be carried out. In this case, the inorganic particles used at sub-step of (a1) are, for example, titania particles and the inorganic particles used at sub-step of (a2) are, for example, silica particles.

Moreover, as step of (b), step (b1) of growing a semiconductor layer on the particles placed at step of (a) and step (b2) of growing another semiconductor layer on the semiconductor layer formed at step of (b1) may be carried out. By carrying out steps of (a) and (b) repeatedly, a free-standing substrate is obtained which is suitable for producing a high brightness semiconductor light-emitting device.

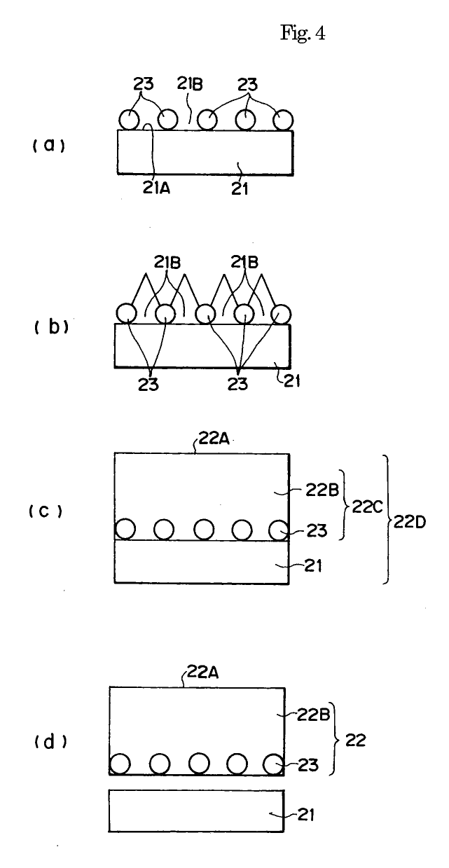

The method for producing a free-standing substrate according to the invention is illustrated below with reference to FIG. 4.

As shown in FIG. 4(a), the inorganic particles 23 are placed on the surface 21A of a substrate 21. As described above, the placement of the inorganic particles 23 may be carried out by the method of dipping the substrate 21 in a slurry prepared by dispersing the inorganic particles 23 into a medium (such as water, methanol, ethanol, isopropanol, n-butanol, ethylene glycol, dimethylacetamide, methyl ethyl ketone, methyl isobutyl ketone, or the like) and then drying the slurry or the method of applying or spraying the slurry onto the surface 21A of the substrate 21 and then drying the slurry.

Then a group III-V nitride semiconductor is epitaxially grown on the substrate 21 so as to embed the inorganic particles 23 placed on the substrate 21, thereby a group III-V nitride semiconductor layer including the inorganic particles is grown. The inorganic particles 23 usually act as a mask in the growth of the group III-V nitride semiconductor, and therefore a portion where no inorganic particle 23 is placed is utilized as the growth region 21B of the semiconductor layer. As shown in FIG. 4(b), when the materials have been supplied, the group III-V nitride semiconductor starts to grow at the growth region 21B through its epitaxial growth and then continues to grow so as to embed the inorganic particles 23 while forming the facet structure. As shown in FIG. 4(c), the lateral growth of the semiconductor layer is promoted after that, thereby the facet structure is embedded therein and the layer itself becomes flattened. Then a group III-V nitride semiconductor layer 22B is grown, thereby a group III-V nitride semiconductor layered substrate 22D is obtained. Crystal defects in the obtained group III-V nitride semiconductor layered substrate 22D are significantly reduced.

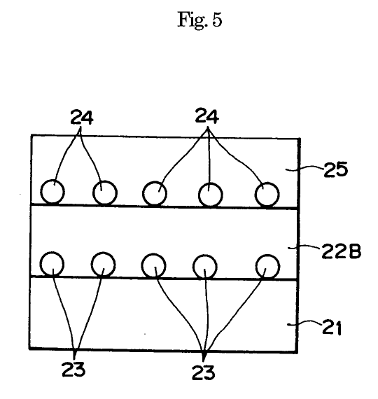

Furthermore, as shown in FIG. 5, after inorganic particles 24 have been placed on the group III-V nitride semiconductor layered substrate 22B, a group III-V nitride semiconductor may be grown by using the inorganic particles 24 as a mask to form a group III-V nitride semiconductor layer 25. The group III-V nitride semiconductor layer 25 may be either an undoped layer or an impurity-doped layer.

As shown in FIG. 4(c), in the growth of the group III-V nitride semiconductor on the substrate 21 on which the inorganic particles 23 are placed, the inorganic particles 23 are present near an interface between the substrate 21 and a group III-V nitride semiconductor layer 22C; to be more specific, the inorganic particles 23 are surrounded with the group III-V nitride semiconductor layer 22 and part of the particles 23 contacts the substrate 21 at the interface between the substrate 21 and the group III-V nitride semiconductor layer 22B.

A bonding strength between the substrate 21 and the group III-V nitride semiconductor crystalline layer 22B of the group III-V nitride semiconductor layered substrate 22D is lower than that between a substrate and a group III-V nitride semiconductor crystalline layer formed without placing the inorganic particles 23.

When the thickness of the group III-V nitride semiconductor layer 22C is increased, internal stress produced by the difference in thermal expansion coefficient and so on between the substrate 21 and the group III-V nitride semiconductor crystalline layer 22B or external stress tends to intensively act on the interface between the substrate 21 and the group III-V nitride semiconductor layer 22C. For example, as shown in FIG. 4(d), these stresses act as stress (shearing stress or the like) exerted on the interface between them. When the level of the stress has become higher than that of the bonding force, rupture takes place near or at the interface between the substrate 21 and the group III-V nitride semiconductor layer 22C, thereby the substrate 21 is removed therefrom, and therefore a free-standing substrate 22 is obtained. The group III-V nitride semiconductor layer 22C has a thickness of usually not less than 3 μm, preferably 10 μm, usually not more than 500 μm, preferably not more than 100 μm, more preferably not more than 65 μm, and further preferably not more than 45 μm.

When the facet structure is formed, the buffer layer may be grown on the substrate and the inorganic particles may be placed on the buffer layer. As the buffer layer, an alloy semiconductor of InN, AlN, and GaN is used, for example; therefore any compound represented by the formula InₓGa_{y}Al_{z}N 1(x+y+z=1, 0≦x≦1, 0≦y≦1, and 0≦z≦1) may be used.

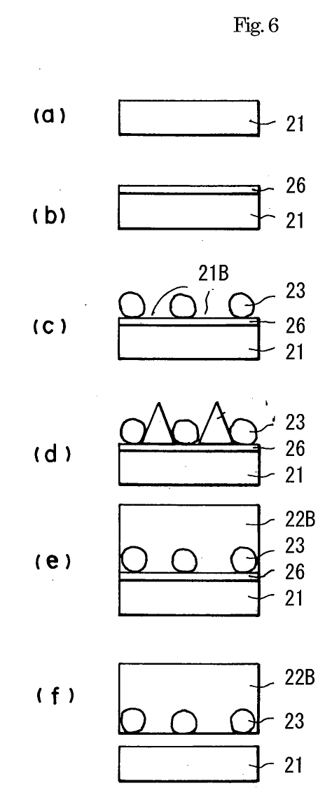

The method for producing the free-standing substrate including the step of forming the buffer layer is illustrated below with reference to FIG. 6. After the buffer layer 26 is grown on the substrate 21 as shown in FIGS. 6(a) and 6(b), the inorganic particles 23 are placed on the buffer layer 26 as shown in FIG. 6(c).

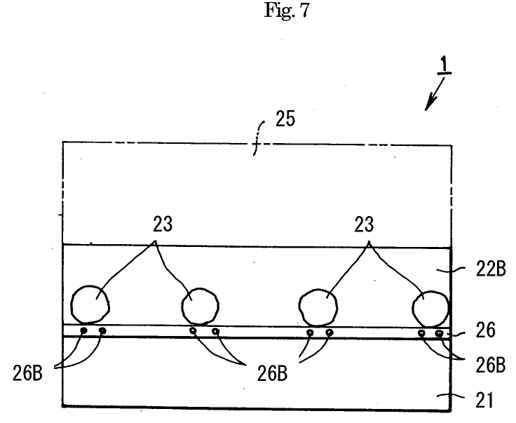

Then a group III-V nitride semiconductor is epitaxially grown on the buffer layer 26 so as to embed the inorganic particles 23 in the semiconductor. As shown in FIG. 6(d), when materials are supplied for the epitaxial growth of the group III-V nitride semiconductor, the nitride semiconductor grows so as to embed the inorganic particles therein while forming a facet structure. Thereafter, as shown in FIG. 6(e), the lateral growth of the group III-V nitride semiconductor is promoted for the embodiment of the facet structure therein and the flattening of the semiconductor itself, thereby the group III-V nitride semiconductor layer 22B is grown. And further, as shown in FIG. 7, another group III-V nitride semiconductor layer 25 may be grown on the group III-V nitride semiconductor layer 22B. Then, as shown in FIG. 6(f), the substrate 21 or both the substrate 21 and the buffer layer 26 (not shown in FIG. 6(f)) are removed due to internal stress or external stress, thereby the free-standing substrate is obtained.

### Semiconductor Light-Emitting Device

A semiconductor light-emitting device according to the present invention includes the free-standing substrate, conductive layers, a light-emitting layer, and electrodes. The semiconductor light-emitting device generally has a double heterostructure, includes the free-standing substrate, the n-type conductive layer, the light-emitting layer, and the p-type conductive layer in that order, and includes the electrodes.

The n-type conductive layer is a n-type contact layer made of, for example, a group III-V nitride represented by the formula InₓGa_{y}Al_{z}N (x+y+z=1, 0≦x<1, 0<y≦1, and 0≦z<1). The n-type contact layer has an n-type carrier concentration of preferably not less than 1×10¹⁸, not more than 1×10¹⁹ cm⁻³ in view of decrease in operating voltage for the semiconductor light-emitting device. In view of the enhancement of the crystallinity of the n-type contact layer, the n-type contact layer has an In content of usually not higher than 5% (that is, x≦0.05), preferably not higher than 1% and an Al content of usually not higher than 5% (that is, z≦0.05), preferably not higher than 1%. The n-type contact layer is more preferably made of GaN.

The light-emitting layer has a barrier layer represented by the formula InₓGa_{y}Al_{z}N (x+y+z=1, 0≦x<1, 0<y≦1, and 0≦z<1) and a quantum well structure built with a well layer represented by the formula InₓGa_{y}Al_{z}N (x+y+z=1, 0≦x<1, 0<y≦1, and 0≦z<1) The quantum well structure may be single or multiple.

The p-type conductive layer is, for example, a p-type contact layer made of a group III-V nitride represented by the formula InₓGa_{y}Al_{z}N (x+y+z=1, 0≦x<1, 0<y≦1, and 0≦z<1). The p-type contact layer has a p-type carrier concentration of not lower than 5×10¹⁵ cm⁻³, preferably not lower than 1×10¹⁶, not more than 5×10¹⁹ cm⁻³ in view of the decrease in the operating voltage for the semiconductor light-emitting device. In view of reduction in contact resistance, the p-type contact layer has an Al content of usually not higher than 5% (that is, x≦0.05), preferably not higher than 1%. The p-type contact layer is preferably made of GaAlN or GaN and more preferably made of GaN.

The electrodes are a negative electrode and a positive electrode. The negative electrode is in contact with the n-type contact layer. The negative electrode is made of, for example, an alloy or a compound including at least one element selected from the group consisting of Al, Ti, and V as a main componet, and preferably made of Al, TiAl, or VAl. The positive electrode is in contact with the p-type contact layer. The positive electrode is made of, for example, NiAu or ITO.

The semiconductor light-emitting device may include a layer made of a group III-V nitride represented by the formula InₓGa_{y}AlₓN (x+y+z=1, 0≦x<1, 0<y≦1, and 0≦z<1) between the n-type semiconductor layer and the light-emitting layer. The group III-V nitride layer may be grown as a single layer or a multilayer comprised of layers differing in their compositions and carrier concentrations.

Moreover, the semiconductor light-emitting device may include a layer made of a group III-V nitride represented by the formula InₓGa_{y}Al_{z}N (x+y+z=1, 0≦x<1, 0<y≦1, and 0≦z<1) and preferably made of AlGaN between the light-emitting layer and the p-type contact layer. The AlGaN layer may be of either a p-type or a n-type. When the AlGaN layer is n-type, its carrier concentration is not higher than 1×10¹⁸ cm⁻³, preferably not higher than 1×10¹⁷ cm⁻³, and more preferably not higher than 5×10¹⁶ cm⁻³.

Furthermore, the semiconductor light-emitting device may include a layer made of a nitride which is represented by the formula InₓGa_{y}Al_{z}N (x+y+z=1, 0≦x<1, 0<y≦1, and 0≦z<1) and which is lower than the AlGaN layer in space charge density between the p-type contact layer and the AlGaN layer.

As shown in FIG. 1, the semiconductor light-emitting device 1 has a structure in which, for example, the n-type contact layer 3, the light-emitting layer 4, and the p-type contact layer 5 are formed on the group III-V nitride free-standing substrate 22 including the inorganic particles 23 in that order. The negative electrode 6 is formed on the n-type contact layer 3 and the positive electrode 7 is formed on the p-type contact layer 5.

The n-type contact layer 3, the light-emitting layer 4, and the p-type contact layer 5 may be grown by means of MOVPE, HVPE, MBE, or the like. In the MOVPE, for example, the growth may be carried out by placing the free-standing substrate 22 into the reactor, growing each layer by supplying each organometallic material and, if necessary, each dopant material while regulating each flow rate, and then heat-treating the layers. For example, a growth temperature for the n-type contact layer 3 is in the range of 850° C. to 1100° C., that for the light-emitting layer 4 is in the range of 600° C. to 1000° C., and that for the p-type contact layer 5 is usually in the range of 800° C. to 1100° C.

### EXAMPLES

The following examples will illustrate the present invention in more detail, but do not limit the scope of the invention.

### Example 1

### Production of Free-Standing Substrate

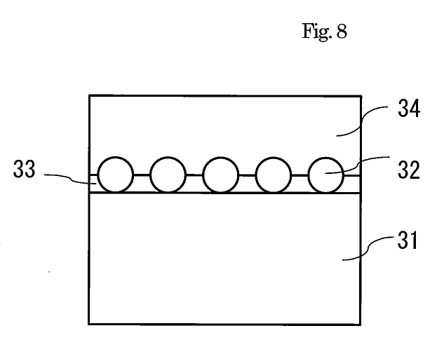

As a substrate 31, a mirror polished c-face sapphire substrate was used. As a material for silica particles 32, colloidal silica (Trade Name “SEAHOSTAR KE-W50”, manufactured by Nippon Shokubai Co., Ltd., average particle diameter: 550 nm) was used. Those reference numerals are based on FIG. 8. The substrate 31 was set onto a spinner, the colloidal silica diluted so as to have a silica content of 10 wt % was applied onto the substrate 31, and the colloidal suspension was spin-dried to place the silica particles 32 on the substrate 31. When observed using a scanning electron microscope, the silica particles 32 were placed as a single layer and the coverage of the silica particles 32 to the surface of the substrate 31 was 36%.

A group III-V nitride semiconductor layer was epitaxially grown thereon by atmospheric pressure MOVPE and the following procedure to grow the group III-V nitride semiconductor layer including the silica particles 32.

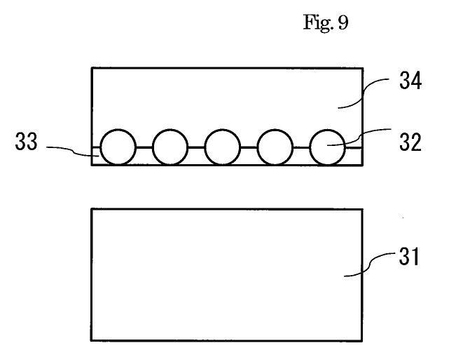

A GaN buffer layer 33 having a thickness of about 500 Å was grown on the substrate 31 under the conditions of pressure: 1 atm, susceptor temperature: 485°, by supplying a carrier gas which is hydrogen, ammonia, and TMG. An undoped GaN layer 34 was grown on the GaN buffer layer 33 by heating the susceptor temperature to 900° C. and supplying the carrier gas, ammonia, and TMG. Further, the undoped GaN layer 34 was grown by heating the susceptor temperature to 1040° C., lowering the reactor pressure to a one-quarter atmospheric pressure, and supplying the carrier gas, ammonia, and TMG. Thereafter, the susceptor temperature was cooled from 1040° C. to room temperature to obtain a free-standing substrate (GaN single crystal, thickness: 45 μm) including the group III-V nitride semiconductor layer including the silica particles 32. The separation was brought about between the substrate 31 and the silica particles 32 (at a surface comprised of the lower portions of the silica particles 32 and the bottom of the GaN buffer layer 33 as shown in FIG. 9).

### Example 2

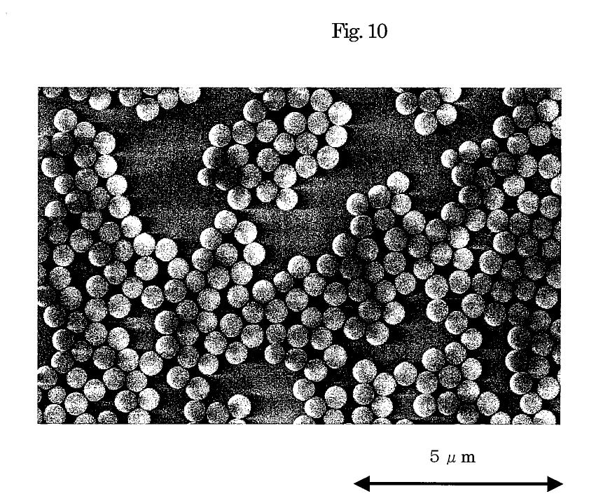

The same operation as [PRODUCTION OF FREE-STANDING SUBSTRATE] of Example 1 was conducted except that the colloidal silica diluted so as to have a silica content of 13 wt % was used to obtain a free-standing substrate. The coverage of the silica particles to the surface of the substrate was 55%. A photograph of the substrate on which the silica particles are placed was shown in FIG. 10. In this example as well, the separation was brought about between the substrate 31 and the silica particles 32.

### Example 3

### Production of Free-Standing Substrate

As a substrate, a mirror polished c-face sapphire substrate was used. As a material for silica particles, colloidal silica (Trade Name “MP-1040”, manufactured by Nissan Chemical Industries Ltd., average particle diameter: 100 nm) was used. The substrate was set onto a spinner, the colloidal silica diluted so as to have a silica content of 10 wt % was applied on the substrate, and the colloidal suspension was spin-dried to place the silica particles on the substrate. The coverage of the silica particles to the surface of the substrate was 55%.

A group III-V nitride semiconductor layer was epitaxially grown thereon by atmospheric pressure MOVPE and the following procedure to form the group III-V nitride semiconductor layer including the silica particles.

A GaN buffer layer having a thickness of about 500 Å was grown on the substrate under the conditions of pressure: 1 atm, susceptor temperature: 485° C. by supplying a carrier gas which is hydrogen, ammonia, and TMG. An undoped AlGaN layer was grown on the GaN buffer layer by heating the susceptor temperature to 800° C. and supplying the carrier gas, ammonia, TMA, and TMG. An undoped GaN layer was grown by heating the susceptor temperature to 1040° C., lowering the reactor pressure to a one-quarter atmospheric pressure, and supplying the carrier gas, ammonia, and TMG. Thereafter, the susceptor temperature was cooled from 1040° C. to room temperature to obtain a free-standing substrate (GaN single crystal, thickness: 12 μm) including the group III-V nitride semiconductor layer including the silica particles. The separation was brought about between the substrate and the silica particles.

### Example 4

The same operation as [PRODUCTION OF FREE-STANDING SUBSTRATE] of Example 3 was conducted except that colloidal silica (Trade Name “MP-4540”, manufactured by Nissan Chemical Industries Ltd., average particle diameter: 450 nm) was used with its silica concentration adjusted to 40 wt % and that the undoped GaN layer was grown up to a thickness of 40 μm to obtain a free-standing substrate (GaN single crystal, thickness: 40 μm) The free-standing substrate had a group III-V nitride semiconductor layer including silica particles was formed. In this Example, the coverage of the silica particles to the surface of the substrate was 71%. The separation was brought about between the substrate and the silica particles.

### Example 5

As a substrate, a mirror polished c-face sapphire substrate was used. As materials for inorganic particles, a titania slurry (Trade Name “NanoTek TiO₂”, manufactured by C.I.Kasei Co., Ltd., average particle diameter: 40 nm, dispersion medium: water) and colloidal silica (Trade Name “MP-1040”, manufactured by Nissan Chemical Industries Ltd., average particle diameter: 100 nm) were used. The substrate was set onto a spinner, the titania slurry diluted so as to have a titania content of 1 wt % was applied on the substrate, and the slurry was spin-dried to place titania particles on the substrate. The coverage of the titania particles to the surface of the substrate was 36%. Furthermore, the colloidal silica with a silica content adjusted to 40 wt % was applied thereon, following which the colloidal suspension was spin-dried to place the silica particles on the substrate. The coverage of the silica particles to the surface of the substrate was 71%.

A group III-V nitride semiconductor layer was epitaxially grown by atmospheric pressure MOVPE and the following procedure to grow the group III-V nitride semiconductor layer including the silica particles.

A GaN buffer layer having a thickness of about 500 Å was grown on the substrate under the conditions of pressure: 1 atm, susceptor temperature: 485° C. by supplying a carrier gas which is hydrogen, ammonia, and TMG. An undoped AlGaN layer was grown on the GaN buffer layer by heating the susceptor temperature to 800° C. and supplying the carrier gas, ammonia, TMA, and TMG. An undoped GaN layer having a thickness of 20 μm was grown by heating the susceptor temperature to 1040° C., lowering the reactor pressure to a one-quarter atmospheric pressure, and supplying the carrier gas, ammonia, and TMG. Thereafter, the susceptor temperature was cooled from 1040° C. to room temperature to obtain a free-standing substrate (GaN single crystal, thickness: 20 μm) having the group III-V nitride semiconductor layer including the titania particles and the silica particles. The separation was brought about between the substrate and the inorganic particles.

### Comparative Example 1

The same operation as [PRODUCTION OF FREE-STANDING SUBSTRATE] of Example 1 was conducted except that no silica particle was placed thereon. In this example, the group III-V nitride semiconductor layer was broken without separating from the substrate.

### Example 6

### Production of Free-Standing Substrate

The free-standing substrate shown in FIG. 6 was produced.

As the substrate 21, a mirror polished c-face sapphire substrate was used. The GaN buffer layer 26 having a thickness of 60 nm was epitaxially grown on the substrate 21 under the conditions of pressure: 1 atm, susceptor temperature: 485° C. by supplying a carrier gas which is hydrogen, ammonia, and TMG by MOVPE. The substrate 21 was taken out of the reactor and then set onto a spinner, following which colloidal silica (Trade Name “SEAHOSTAR KE-W50” from Nippon Shokubai Co., Ltd., average particle diameter: 500 nm) was applied on the substrate 21 with the colloidal suspension diluted so as to have a silica content of 10 wt %. Thereafter, the colloidal suspension was spin-dried to place the silica particles 23 on the GaN buffer layer 26. When observed using a scanning electron microscope, the silica particles were placed at a single layer and the coverage of the silica particles to the surface of the GaN buffer layer 26 was 36%.

The substrate 21 is placed into the reactor and a group III-V nitride semiconductor layer was epitaxially grown on the substrate 21 by atmospheric pressure MOVPE and the following procedure to form the group III-V nitride semiconductor layer 22B including the silica particles 23.

The undoped GaN layer 22B was grown thereon under conditions of pressure: 500 Torr, susceptor temperature: 1020° C. by supplying a carrier gas which is hydrogen, ammonia 4.0 slm, and TMG 20 sccm for 75 minutes. The undoped GaN layer 22B was grown by heating the susceptor temperature to 1120° C. and supplying the carrier gas, ammonia 4.0 slm, and TMG 35 sccm for 90 minutes. Further, the undoped GaN layer 22B was grown by cooling the susceptor temperature to 1080° C. with the pressure maintained at 500 Torr and supplying the carrier gas, ammonia 4.0 slm, and TMG 50 sccm for 360 minutes. Thereafter, the susceptor temperature was cooled from 1080° C. to room temperature to obtain a free-standing substrate (GaN single crystal, thickness: 35 μm) having the group III-V nitride semiconductor layer including the silica particles 23. The separation was brought about between the substrate 21 and a portion on the substrate 21 side of the silica particles 23.

### Comparative Example 2

The same operation as [PRODUCTION OF FREE-STANDING SUBSTRATE] of Example 4 was conducted except that no silica particle was placed thereon. In this example, the semiconductor layer 22B was not separated from the substrate 21.

### Example 7

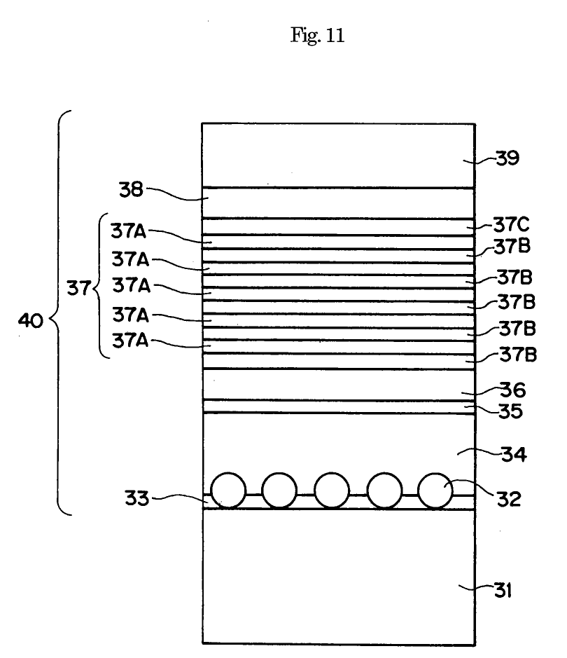

A semiconductor light-emitting device with a layered structure shown in FIG. 11 was produced.

### [Production of Substrate for Semiconductor Light-Emitting Device]

After the growth of the undoped GaN layer 34 described in [PRODUCTION OF FREE-STANDING SUBSTRATE] of Example 1, a Si-doped GaN layer 35 having a thickness of about 3.5 μm was grown on the undoped GaN layer 34 as a n-type contact layer without cooling to room temperature, following which a light-emitting layer 37 was grown according to the following procedure. After a GaN layer 36 was grown by cooling the reactor temperature to 780° C. and using nitrogen as a carrier gas, an InGaN layer 37A having a thickness of 3 nm and a GaN layer 37B having a thickness of 18 nm were alternately grown five times respectively. Then a GaN layer 37C having a thickness of 18 nm was grown on the InGaN layer 37A to obtain the light-emitting layer 37.

A Mg-doped AlGaN layer 38 having an Al content of 0.05% and a thickness of 25 nm was grown on the GaN layer 37C. A Mg-doped GaN layer 39 having a thickness of 150 nm was grown on the AlGaN layer 38 by heating the reactor temperature to 1040° C. and supplying a carrier gas, ammonia, TMG, and (C₅H₄C₂H₅)₂Mg(EtCp₂Mg) for 30 minutes. Thereafter, the reactor temperature was cooled to room temperature to obtain a substrate 40 for the group III-V nitride semiconductor light-emitting device. The substrate 40 contained the semiconductor layers and the free-standing substrate having the group III-V nitride semiconductor layer including the silica particles 32. The separation was brought about between the substrate 31 and the silica particles 32.

### [Formation of Electrodes]

A resist pattern for a positive electrode was formed on the Mg-doped GaN layer 39 of the substrate 40 for the group III-V nitride semiconductor light-emitting device by photolithography. NiAu was vacuum evaporated thereon. An electrode pattern was formed using lift-off process, and heat treatment was conducted to obtain an ohmic positive electrode with an area of 3.14×10⁻⁴ cm². Then a mask pattern was formed by photolithography. A dry etching was carried out to expose the Si-doped GaN layer 35. After removing the mask, a resist pattern for a negative electrode was formed on the dry-etched surface by photolithography. Al was vacuum evaporated thereon. An electrode pattern was formed using lift-off process to obtain a negative electrode.

### [Evaluation of Semiconductor Light-Emitting Device]

The emission properties of the semiconductor light-emitting device was determined by applying a voltage to the device in the form of a substrate. The wavelength of emitted light was 440 nm and a light output was 10.2 mW (at a forward current of 20 mA).

### Comparative Example 3

The same operation as [PRODUCTION OF SUBSTRATE FOR SEMICONDUCTOR LIGHT-EMITTING DEVICE] of Example 7 was conducted except that no silica particle was placed thereon and that a substrate was removed from the substrate for a semiconductor light-emitting device using laser lift-off process to obtain a substrate. Then the same operation as [FORMATION OF ELECTRODES] of Example 7 was conducted to obtain a semiconductor light-emitting device. As a result of evaluating the semiconductor light-emitting device under the same conditions as [Evaluation of Semiconductor Light-Emitting Device] of Example 7, the wavelength of emitted light was 440 nm and a light output was 4.0 mW (at a forward current of 20 mA).

1. A free-standing substrate comprising a semiconductor layer and inorganic particles, wherein the inorganic particles are included in the semiconductor layer.

2. The free-standing substrate according to claim 1, wherein the semiconductor layer includes a metallic nitride at a portion where the inorganic particles are not present.

3. The free-standing substrate according to claim 1, wherein the inorganic particles are made of at least one selected from the group consisting of oxide, nitride, carbide, boride, sulfide, selenide, and metal.

4. The free-standing substrate according to claim 3, wherein the inorganic particles are made of oxide.

5. The free-standing substrate according to claim 4, wherein the oxide is at least one selected from the group consisting of silica, alumina, zirconia, titania, ceria, magnesia, zinc oxide, tin oxide, and yttrium aluminum garnet.

6. The free-standing substrate according to claim 5, wherein the oxide is silica.

7. The free-standing substrate according to claim 1, wherein the inorganic particles include a mask material for the growth of the semiconductor layer.

8. The free-standing substrate according to claim 7, wherein the surfaces of the inorganic particles are covered with the mask material.

9. The free-standing substrate according to claim 7, wherein the mask material is at least one selected from the group consisting of silica, zirconia, titania, silicon nitride, boron nitride, W, Mo, Cr, Co, Si, Au, Zr, Ta, Ti, Nb, Pt, V, Hf, and Pd.

10. The free-standing substrate according to claim 1, wherein the inorganic particles have the shape of sphere, plate or needle, or no definite shape.

11. The free-standing substrate according to claim 10, wherein the inorganic particles have the shape of sphere.

12. The free-standing substrate according to claim 1, wherein the inorganic particles have an average particle diameter of not less than 5 nm and not more than 50 μm.

13. A method for producing a free-standing substrate comprising the steps of:
(a) placing inorganic particles on a substrate,
(b) growing a semiconductor layer thereon, and
(c) separating the semiconductor layer from the substrate, in that order.

14. A method for producing a free-standing substrate comprising the steps of:
(s1) growing a buffer layer on a substrate,
(a) placing inorganic particles on the buffer layer,
(b) growing a semiconductor layer thereon; and
(c) separating the semiconductor layer from the substrate, in that order.

15. The method according to claim 13 or 14, wherein the substrate is made of at least one selected from the group consisting of sapphire, SiC, Si, MgAl₂O₄, LiTaO₃, ZrB₂, and CrB₂.

16. The method according to claim 13 or 14, wherein the inorganic particles are made of at least one selected from the group consisting of oxide, nitride, carbide, boride, sulfide, selenide, and metal.

17. The method according to claim 16, wherein the inorganic particles are made of oxide.

18. The method according to claim 17, wherein the oxide is at least one selected from the group consisting of silica, alumina, zirconia, titania, ceria, magnesia, zinc oxide, tin oxide, and yttrium aluminum garnet.

19. The method according to claim 18, wherein the oxide is silica.

20. The method according to claim 13 or 14, wherein the inorganic particles have the shape of sphere, plate or needle, or no definite shape.

21. The method according to claim 20, wherein the inorganic particles have the shape of sphere.

22. The method according to claim 13 or 14, wherein the inorganic particles have an average particle diameter of not less than 5 nm and not more than 50 μm.

23. The method according to claim 13 or 14, wherein the semiconductor layer is made of group III-V nitride represented bythe formula InₓGa_{y}Al_{z}N (0≦x≦1, 0≦y≦1, 0≦z≦1, and x+y+z=1).

24. The method according to claim 13 or 14, wherein the step (a) comprises sub-step (a1) of placing the inorganic particles thereon and sub-step (a2) of placing another type of inorganic particles thereon.

25. The method according to claim 24, wherein the inorganic particles used at the sub-step (a1) are made of titania.

26. The method according to claim 24, wherein the organic particles used at the sub-step (a2) are made of silica.

27. A semiconductor light-emitting device comprising the free-standing substrate according to claim 1, a conductive layer, a light-emitting device, and electrodes.
